(19) United States
(12) Patent Application Publication
(10) Pub. No.: US 2004/0187050 A1
(43) Pub. Date: Sep. 23, 2004

(54) Test structure and method for accurate determination of soft error of logic components

(76) Inventors: Robert Christopher Baumann, Dallas, TX (US); Xiaowei Deng, Plano, TX (US)

Correspondence Address: TEXAS INSTRUMENTS INCORPORATED, P O BOX 655474, M/S 3999, DALLAS, TX, 75265

(21) Appl. No.: 10/392,099

(22) Filed: Mar. 19, 2003

(51) Int. Cl. G06F 11/00; G01R 31/28

(52) U.S. Cl. 714/704; 714/735

(57) ABSTRACT

A system and associated methodology are disclosed for characterizing soft error or failure rates of electronic circuit elements, where the elements are suitable for use as non-memory peripheral logic in semiconductor memory devices, and where the probability of such soft error or failure rates increases as charge sensitive interconnections or nodes of the elements are exposed to radiation, and as scaling continues and voltages and capacitances are thereby reduced.

### FIELD OF INVENTION

The present invention relates generally to semiconductor memory devices and more particularly to testing of electronic elements for soft error rates, where such elements are suitable for use as non-memory peripheral logic in semiconductor memory devices.

### BACKGROUND OF THE INVENTION

Several trends presently exist in the semiconductor device fabrication industry and in the electronics industry. Devices are continually getting smaller, faster and requiring less power, while simultaneously being able to support a greater number of increasingly sophisticated applications. One reason for these trends is that there is an ever increasing demand for small, portable and multifunctional electronic devices. For example, cellular phones, personal computing devices, and personal sound systems are devices which are in great demand in the consumer market. These devices rely on one or more small batteries, which are generally rechargeable, as a power source and also require an ever increasing storage capacity to store data, such as digital audio, digital video, contact information, database data and the like.

To achieve these and other ends, a continuing trend in the semiconductor manufacturing industry is toward producing smaller and faster transistor devices, which consume less power and provide more memory density. Integrated circuits (ICs) are thus continually designed with a greater number of layers and with reduced feature sizes and distances between features (e.g., at sub micron levels). This can include the width and spacing of interconnecting lines, the spacing and diameter of contact holes, and the surface geometry such as corners and edges of various features. The scaling-down of integrated circuit dimensions can facilitate faster circuit performance, more memory and can lead to higher effective yield in IC fabrication by providing more circuits on a die and/or more die per semiconductor wafer.

Semiconductor based products (e.g., DSP, microprocessors) can include one or more different types of memory, such as static random access memory (SRAM), dynamic random access memory (DRAM) and/or embedded memory, as well as glue logic which generally comprises latches, flip-flops and combinatorial logic that interconnects the memory to cache(s). The memories generally include thousands or millions of memory cells, adapted to individually store and provide access to data. A typical memory cell stores a single binary piece of information referred to as a bit. The cells are commonly organized into multiple cell units such as bytes which generally comprise eight cells, and words which may include sixteen or more such cells, usually configured in multiples of eight. Storage of data in such memory device architectures is performed by writing to a particular set of memory cells, sometimes referred to as programming the cells. Retrieval of data from the cells is accomplished in a read operation. In addition to programming and read operations, groups of cells in a memory device may be erased.

The erase, program, and read operations are commonly performed by application of appropriate voltages to certain terminals or nodes of the cells. In an erase or program operation the voltages are applied so as to cause a charge to be stored in the memory cells. In a read operation, appropriate voltages are applied so as to cause a current to flow in the cells, wherein the amount of such current is indicative of the value of the data stored in the respective cells. The memory devices include appropriate circuitry to sense the resulting cell currents in order to determine the data stored therein, which may then be provided to data bus terminals for access by other devices in a system in which the memory device is employed.

### SUMMARY OF THE INVENTION

The following presents a simplified summary of the invention in order to provide a basic understanding of some aspects of the invention. This summary is not an extensive overview of the invention. It is intended neither to identify key or critical elements of the invention nor to delineate the scope of the invention. Rather, its purpose is merely to present one or more concepts of the invention in a simplified form as a prelude to the more detailed description that is presented later.

One or more aspects of the present invention pertain to characterizing soft error or failure rates of electronic circuit elements, where the elements are suitable for use as non-memory peripheral logic in semiconductor memory devices, and as the elements, and more particularly charge sensitive interconnections or nodes thereof, are exposed to and affected by radiation.

According to one or more aspects of the present invention, a method of testing for a soft error rate of a type of electronic circuit element is disclosed, wherein the element is suitable for use as non-memory peripheral logic in semiconductor memory devices. The method includes exposing a plurality of elements of the element type to be tested to radiation, wherein the elements are arranged in series as a string. Data is clocked into the string of elements and read out from the string of elements while the elements are exposed to the radiation. Read out data is then compared to clocked in data for a determination of soft error.

According to one or more other aspects of the present invention, a test system is disclosed that is adapted to determine a soft error rate of a type of electronic circuit element, where the element is suitable for use as non-memory peripheral logic in semiconductor memory devices. The system includes a string of elements of the type of element to be tested as well as a component adapted to input data into the string. A radiation source is also included and is operable to expose the elements to radiation to mimic one or more operating conditions that the element would actually encounter in the field. Another component is included to read out data from the string of elements, and a final component is included to compare the input data to the output data to determine whether the input data has changed upon passing through the string of elements while being exposed to the radiation and thus whether any soft errors have occurred.

To the accomplishment of the foregoing and related ends, the following description and annexed drawings set forth in detail certain illustrative aspects and implementations of the invention. These are indicative of but a few of the various ways in which one or more aspects of the present invention may be employed. Other aspects, advantages and novel features of the invention will become apparent from the following detailed description of the invention when considered in conjunction with the annexed drawings.

### BRIEF DESCRIPTION OF THE DRAWINGS

FIG. 1 is a plan view of an exemplary memory device.

FIG. 2 illustrates an exemplary DRAM memory device in schematic block diagram form.

FIG. 3 illustrates in schematic block diagram form a system according to one or more aspects of the present invention that facilitates testing for and/or characterizing soft error or failure rates in elements suitable for use as non-memory peripheral logic in semiconductor products.

FIG. 4 illustrates a plurality of elements strung together in a compact arrangement suitable for testing in accordance with one or more aspects of the present invention.

FIG. 5 is yet another illustration of a plurality of elements strung together in a compact arrangement suitable for testing in accordance with one or more aspects of the present invention.

FIG. 6 illustrates an arrangement of one or more components of a system suitable to concurrently determine respective soft error rates of different types of elements suitable for use as non-memory peripheral logic.

FIG. 7 illustrates an exemplary plot of element type/critical charge versus respective failure rates for the elements.

FIG. 8 illustrates an exemplary characterization box including failure rates for respective element types given certain test conditions.

FIG. 9 illustrates a flow diagram of a methodology for determining soft error rates of an element suitable for use as non-memory peripheral logic in semiconductor devices according to another aspect of the present invention.

### DETAILED DESCRIPTION OF THE INVENTION

One or more aspects of the present invention are described with reference to the drawings, wherein like reference numerals are generally utilized to refer to like elements throughout, and wherein the various structures are not necessarily drawn to scale. In the following description, for purposes of explanation, numerous specific details are set forth in order to provide a thorough understanding of one or more aspects of the present invention. It may be evident, however, that one or more aspects of the present invention may be practiced with a lesser degree of these specific details. In other instances, structures and devices are shown in block diagram form in order to facilitate describing one or more aspects of the present invention.

One or more aspects of the present invention generally relate to semiconductor devices that include, among other things, memory, such as static random access memory (SRAM) and/or dynamic random access memory (DRAM), and non-memory peripheral logic or glue logic including latches, flip-flops and/or other combinatorial logic that, among other things, interconnects memory and cache(s), where these elements possess charge-sensitive interconnections or nodes whose performances can be affected by the presence of radiation, and which can experience increased soft error rates as a result of the radiation as well as by scaling whereby voltages and capacitances are reduced within the elements.

More particularly, one or more aspects of the present invention pertain to test systems and associated methodologies that can be utilized to characterize or develop soft error or failure rate data for the non-memory peripheral elements as a function of radiation and/or scaling. Actual circuit elements (e.g., flip-flops, latches and/or other logic devices) are tested. Elements thought to have the greatest and lowest probability of exhibiting soft errors are chosen for testing to define a characterization box or upper and lower performance parameters for particular element types. In this manner, most all of the respective error rates for particular element types fall somewhere in between the respective extremes for the different types of elements.

It will be appreciated that electronic memory devices include a plurality of individual cells that are organized into individually addressable units or groups such as bytes or words, which are accessed for read, program, or erase operations through address decoding circuitry, whereby such operations may be performed on the cells within a specific byte or word. The memory devices include appropriate decoding and group selection circuitry to address such bytes or words, as well as circuitry to provide voltages to the cells being operated on in order to achieve the desired operation.

In a random access memory (RAM), for example, an individual binary data state (e.g., a bit) is stored in a volatile memory cell, wherein a number of such cells are grouped together into arrays of columns and rows accessible in random fashion along bitlines and wordlines, respectively, wherein each cell is associated with a unique wordline and bitline pair. Address decoder control circuits identify one or more cells to be accessed in a particular memory operation for reading or writing, wherein the memory cells are typically accessed in groups of bytes or words (e.g., generally a multiple of 8 cells arranged along a common wordline). Thus, by specifying an address, a RAM is able to access a single byte or word in an array of many cells, so as to read or write data from or into that addressed memory cell group.

Two major classes of random access memories include dynamic (e.g., DRAM) and static (e.g., SRAM) devices. For a DRAM device, data is stored in a capacitor, where an access transistor gated by a wordline selectively couples the capacitor to a bit line. DRAMs are relatively simple, and typically occupy less area than SRAMs. However, DRAMs require periodic refreshing of the stored data, because the charge stored in the cell capacitors tends to dissipate. Accordingly DRAMs need to be refreshed periodically in order to preserve the content of the memory. SRAM devices, on the other hand, do not need to be refreshed. SRAM cells typically include several transistors configured as a flip-flop having two stable states, representative of two binary data states. Since the SRAM cells include several transistors, however, SRAM cells occupy more area than do DRAM cells. However, SRAM cells operate relatively quickly and do not require refreshing and the associated logic circuitry for refresh operations.

Other types of memory also exist, such as Flash and EEPROM, which overcome a major disadvantage of SRAM and DRAM devices, namely volatility. SRAM and DRAM devices are said to be volatile as they lose data stored therein when power for such devices is removed. For instance, the charge stored in DRAM cell capacitors dissipates after power has been removed, and the voltage used to preserve the flip-flop data states in SRAM cells drops to zero, by which the flip-flop loses its data. Flash and EEPROM devices are said to be non-volatile as they do not lose data stored therein when power is removed. However, these types of memory devices have operational limitations on the number of write cycles. For instance, Flash memory devices generally have life spans from 100K to 10MEG write operations.

Table 1 illustrates the differences between different types of memory.

TABLE 1

| | | | | FRAM |
|---|---|---|---|---|
| Property | SRAM | Flash | DRAM | (Demo) |
| Voltage | >0.5 V | Read >0.5 V | >1 V | 3.3 V |
| | | Write (12 V) | | |
| | | (±6 V) | | |
| Special Transistors | NO | YES | YES | NO |
| | | (High Voltage) | (Low | |
| | | | Leakage) | |
| Write Time | <10 ns | 100 ms | <30 ns | 60 ns |
| Write Endurance | >10¹⁵ | <10⁵ | >10¹⁵ | >10¹³ |
| Read Time (single/ | <10 ns | <30 ns | <30 ns/<2 ns | 60 ns |
| multi bit) | | | | |
| Read Endurance | >10¹⁵ | >10¹⁵ | >10¹⁵ | >10¹³ |
| Added Mask for | 0 | ˜6-8 | ˜6-8 | ˜3 |
| embedded | | | | |
| Cell Size (F˜metal | ˜80 F² | ˜8 F² | ˜8 F² | ˜18 F² |
| pitch/2) | | | | |
| Architecture | NDRO | NDRO | DRO | DRO |
| Non volatile | NO | YES | NO | YES |
| Storage | I | Q | Q | P |

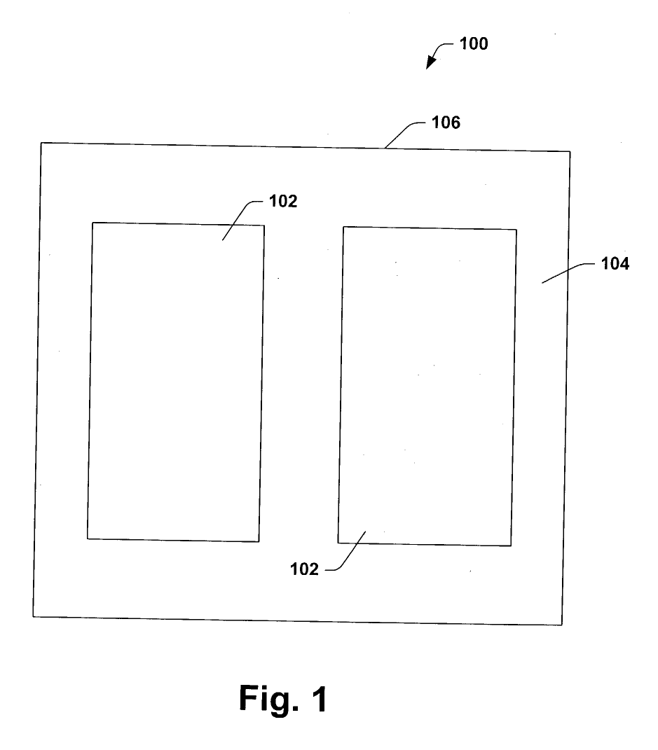

Turning now to FIG. 1, a plan view of an exemplary memory device 100 is depicted. The memory device 100 may comprise one or more core regions 102 and a peripheral portion 104 on a single substrate 106. The core regions 102 typically comprise at least one MxN array of individually addressable, substantially identical memory cells, and the peripheral portion 104 typically includes, among other things logic elements, such as gates, registers, flip-flops and latches that are effective to, among other things, form input/output (I/O) circuitry and/or other circuitry that facilitates selectively addressing the individual cells (e.g., decoders for connecting source, gate and drain regions of selected cells to predetermined voltages or impedances to produce designated operations of the cell, such as programming, reading and/or erasing).

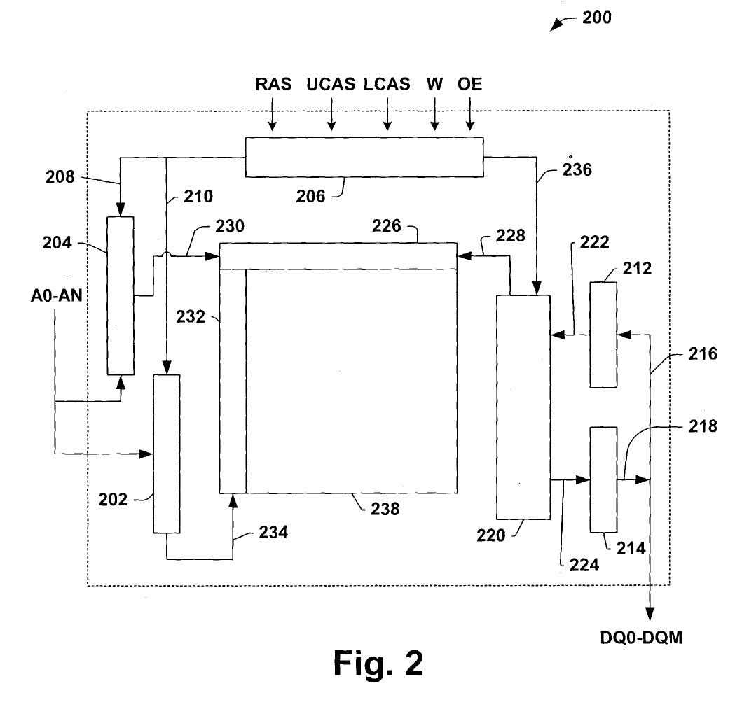

By way of further example, an example of a DRAM memory device 200 is illustrated in somewhat greater detail in schematic block diagram form in FIG. 2. It will be appreciated, however, that application of one or more aspects of the present invention is in no way meant to be limited to a DRAM, but that the instant discussion is merely provided for exemplary purposes. The memory device 200 receives address signals A0-AN, N being an integer, in row address buffers 202 and column address buffers 204. The address signals become latched in the address buffers by use of control signals, for example, RAS (Row Address Strobe), UCAS (Upper Column Address Strobe), and LCAS (Lower Column Address Strobe) received in timing and control block 206. Desired timing and control signals are then carried from control block 206 to buffers 202, 204 via leads 208, 210.

Data signals DQ0-DQM, M being an integer, are carried in parallel to data in register 212 and data out register 214 via leads 216, 218, respectively. A plurality of data signals (e.g., eighteen) pass in parallel from data in register 212 to the I/O buffer 220 via lead 222. Similarly, a plurality of data signals (e.g., eighteen) pass in parallel from the I/O buffer 220 to the data out register 214 via lead 224. A plurality of data signals (e.g., thirty six) also pass in parallel from the I/O buffer 220 to one or more column decoders 226 via lead 228. The column decoders 226 also receive a plurality of address signals (e.g., eight) in parallel from column address buffers 204 via lead 230. Row decoders 232 similarly receive a plurality of address signals (e.g., twelve) in parallel from row address buffers 202 via lead 234. The I/O buffer 220 receives timing and/or control signals from the timing and control block 206 via lead 236. Control signals W (Write) and OE (Output Enable) connect to timing and control block 206 to indicate and control the writing and reading of data signals from overall array 238.

It will be appreciated that column decoders 226 and row decoders 232 can address individual memory cells contained within the overall array 238, and that the overall array 238 can include, for example, 18,874,368 (18M) memory cells, where each memory cell is capable of containing one data bit, which can, for example, be configured in 1,048,576 words by 18 bits per word (1M.times.18). It will be further appreciated that the overall array 238 can contain a plurality of array parts (e.g. seventy two), where respective array parts contain a plurality of memory cells (e.g., 256K). The overall array 238 can also be separated into two halves where the row decoders 232 separate the two halves and where a plurality of array paths (e.g., thirty six) are then located on either side of the row decoders 232.

It will be appreciated that parts of the device, such as the memory cells and non-memory peripheral or glue logic (e.g., 202, 204, 206, 212, 214, 220 as well as other elements which may or may not be shown in the example illustrated) can include charge-sensitive interconnections or nodes which may be affected by radiation, such as by being induced with additional charge, which can cause failures or soft errors. The errors are referred to as soft errors because, while data may be corrupted, these elements themselves remain unaffected.

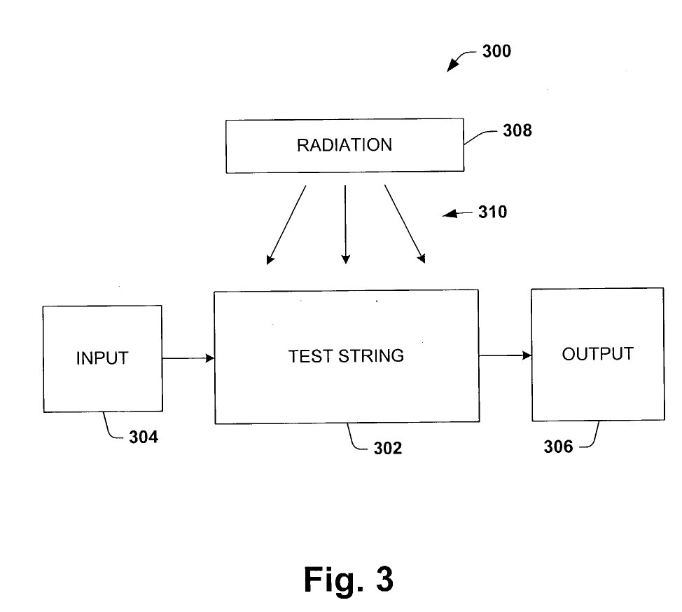

Turning to FIG. 3, a system, according to one or more aspects of the present invention, is depicted in schematic block diagram form which facilitates testing for and/or characterizing soft error or failure rates in elements, such as latches, flip-flops and/or combinatorial or other logic (e.g., NAND gates, NOR gates or the like) suitable for use as non-memory peripheral logic in semiconductor products such as, for example, static random access memory (SRAM). A test string, 302, input 304, output 306 and a source of radiation 308 are shown. The test string 302 includes a length of elements of a particular circuit element, and more particularly a type of element to be tested or characterized (e.g., flip-flop_{A}, flip-flop_{B}, flip-flop_{C}, etc.).

The radiation source 308 is operative to selectively expose the elements in the test string to one or more types of radiation 310 for a particular period of time and/or at a particular intensity to mimic actual operating conditions to which the elements may be subjected while in the field (e.g., when utilized as non-memory peripheral logic, glue logic and/or combinatorial logic in semiconductor memory devices). Such radiation can include, for example, alpha particles, neutrons from cosmic rays and/or ionizing radiation, that can include electromagnetic and/or particulate radiation that produces electron-hole pairs when passing through a medium. An ion, generally speaking, is an atom or molecule which has a resultant electric charge due to loss or gain of one or more electrons. Upon interaction with a semiconductor device, the radiation can cause a disruption in an electrical signal or can corrupt information stored in localized nodes on the device. Such a failure may be referred to as a soft error because only the data is corrupted while the circuit itself remains unaffected.

Further, the radiation applied to the elements can generate a charge on junctions or nodes within the elements being tested. This charge is sometimes referred to as critical charge or signal to noise margin. Some junctions within the elements are driven to have particular charges, while others are floating nodes and/or are very weakly driven. If more charge exists on a node or if a node is being driven to provide additional charge to compensate for radiation induced charge, then the probability of a soft error occurring is significantly reduced. Thus, an element with a relatively high critical charge is difficult to upset and does not readily exhibit soft errors. As a corollary, an element that is sensitive to the external radiation and that has a relatively low critical charge is easily upset and can exhibit soft errors when exposed to even mild spurious charges.

Nevertheless, there is not necessarily a one-to-one correspondence between critical charge and soft error, and thus two elements can have similar critical charges yet have different soft error rates. Accordingly, while one may anticipate different elements to have similar soft error rates, where those elements have similar critical charges, the elements may in fact have different soft error rates. Thus, developing failure rate characterization data facilitates determining what the soft error rates will actually be for particular elements or logic cells, regardless of the critical charges of those elements. This removes ambiguity and/or unreliability present in resulting semiconductor devices, and allows for an estimate of soft error performance.

The test string 302 is comprised of a particular number or length of elements to facilitate a desired failure rate amplification or magnification. For example, when a single element is exposed to the source of radiation, there is some probability that the element will fail a certain number of times in a given time frame. The inventors of the present invention appreciated that by chaining many elements together (e.g., on the order of thousands, hundreds of thousands or millions) the chances of an error occurring are greatly increased. This is true even though the probability that a single element will have an error does not change. In the absence of stringing many elements together, because the occurrence of errors is relatively rare, it may take years, for example, to obtain such failure rate data.

The elements can be tested in static or dynamic modes. By way of example, where the chain includes one thousand elements and is operated in a static mode, the input 304 causes one thousand data bits (e.g., of 1's and/or 0's) to be written into the string by cycling a clock to the chain one thousand times while inputting data to the string. Once the test string or buffer 302 is full of data, the elements are exposed to radiation 310 of a particular type and/or intensity for a particular period of time. The radiation is then removed and the data is read out at the output 306. The read out data is compared to the input data to see if any of the data has changed, and thus whether any soft errors have occurred. For example, if all 1's were clocked into the test string 302 and five 0's appeared at the output 306, then the element being tested could be said to have a soft error or failure rate of five per thousand for the given test conditions (e.g., radiation type, radiation intensity).

In a dynamic mode, the input 304 causes data to be continuously clocked into the string 302 while the string is exposed to the radiation 310. The data passes through the string while the string remains exposed to the radiation and exits the string at the output 306. Input and output data are once again compared, and any changes in the data are indicative of soft errors and thus provide soft error characterization data for the particular type of element being tested for the specific operating conditions.

It will be appreciated that while an arrangement of a string of elements is described, any suitable configuration of elements can be implemented according to one or more aspects of the present invention. For example, the elements to be tested can be arranged in parallel and/or as an XY array, such as the memory elements described with respect to FIGS. 1 and 2, but with a plurality of latches, flip-flops, combinatorial elements, or other types of elements to be tested replacing the memory cells within the array.

It will be appreciated that obtaining this failure rate information may be valuable as the non-memory peripheral elements may define the soft error or failure rates of end products. For example, advanced chips sporting several megabytes of uncorrected embedded SRAM can easily exhibit error rates in excess of one million failures in time (FIT), where one FIT corresponds to one failure per billion chip-hours.

While error correction may be available to mitigate embedded memory soft errors, such correction techniques are not applicable to non-memory peripheral logic, and thus the ultimate soft error rate of the product may be defined by non-memory peripheral logic soft failures. Error correction allows data that is being read or transmitted to be checked for errors and, when necessary, corrected on the fly. Error correction is increasingly being designed into data storage and transmission hardware as data rates (and therefore error rates) increase.

With regard to data storage, error correction works as follows. When a unit of data or a word is stored in RAM, a code that describes the bit sequence in the word is calculated and stored along with the unit of data. For each 64-bit word, an extra 7 bits are needed to store this code. When the unit of data is requested for reading, a code for the stored and about-to-be-read word is again calculated using an algorithm. The newly generated code is compared with the code generated when the word was stored.

If the codes match, the data is free of errors and is sent. If the codes do not match, the missing or erroneous bits are determined through the code comparison and the bit or bits are supplied or corrected. No attempt is made to correct the data that is still in storage. Eventually, it will be overlaid by new data and, assuming the errors were transient, the incorrect bits will go away. Any error that recurs at the same place in storage after the system has been turned off and on again indicate a permanent hardware error and a message is sent to a log or to a system administrator indicating the location with the recurrent errors. In general, error correction increases the reliability of any computing or telecommunications system (or part of a system) without adding much cost.

Nevertheless, while error correction may be available to mitigate or make failures that occur in the memory appear invisible, and thus make memory seem substantially failure free, or at least have a failure rate that is several orders of magnitude lower than it actually is, error correction does not affect peripheral logic, and thus the peripheral logic effectively governs the reliability of resulting devices.

Additionally, failure rates of non-memory peripheral elements can be increasingly problematic as technologies are continually scaled to lower voltages and higher speeds, which increases the sensitivity of the elements. The non-memory peripheral logic may also be scaled at a pace greater than that of the core or embedded memory. For example, conventionally, it was presumed that SRAM was about ten thousand times more likely to fail than peripheral logic, which is no longer true.

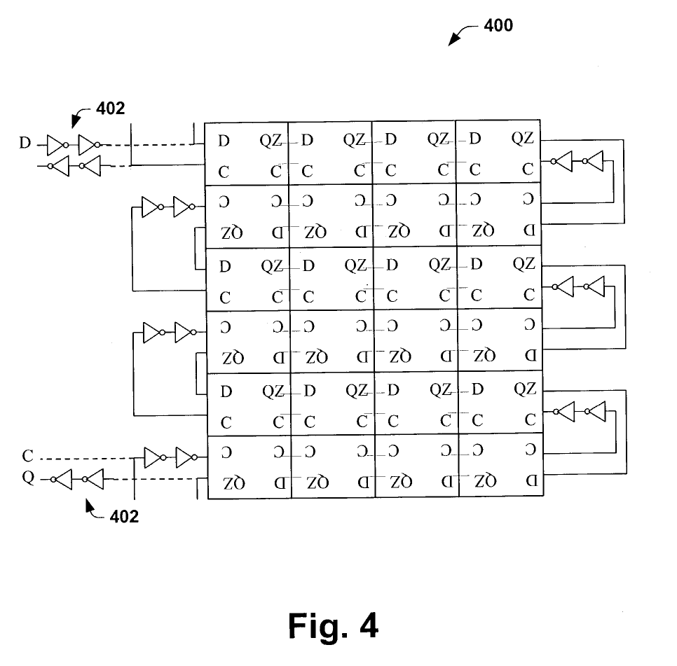

Turning to FIG. 4, a plurality of exemplary non-memory peripheral elements 400 are strung together for testing in accordance with one or more aspects of the present invention. In the configuration illustrated, the elements are compactly arranged as a 6×4 array and include multiple flip-flops of a particular type to be tested (e.g., a D flip-flop). The flip-flops are strung together as synchronously clocked serial first in, first out (FIFO) buffers or chains, where the output of one flip-flop feeds into or acts as an input to another flip-flop. More particularly, a clock signal “C” is included to cycle or drive data “D” into the string, where the output “Q” of respective flip-flops feeds into subsequent flip-flops.

It will be appreciated that such a chain can be of any length, and that while 24 elements are shown in the example illustrated, any number of elements can be included to obtain desired data in a reasonable amount of time. For instance, as scaling occurs the lengths of chains can be decreased since the probability of failure will increase as the elements become more and more sensitive due to the effects of scaling (e.g., lowered voltages, etc.). Nevertheless, generally speaking about a thousand or more elements may need to be chained together to obtain the test data in a reasonable amount of time.

Additionally, the length of such a chain can affect signal integrity (e.g., as the clock may have to drive hundreds of thousands of gates). As such, double pairs of inverters 402 may be included to act as buffers. The inverters can be scaled to whatever size is necessary to provide an appropriate driving signal. The inverters can be placed every so often (e.g., every 16 or 32 stages) within the chain to mitigate signal degradation.

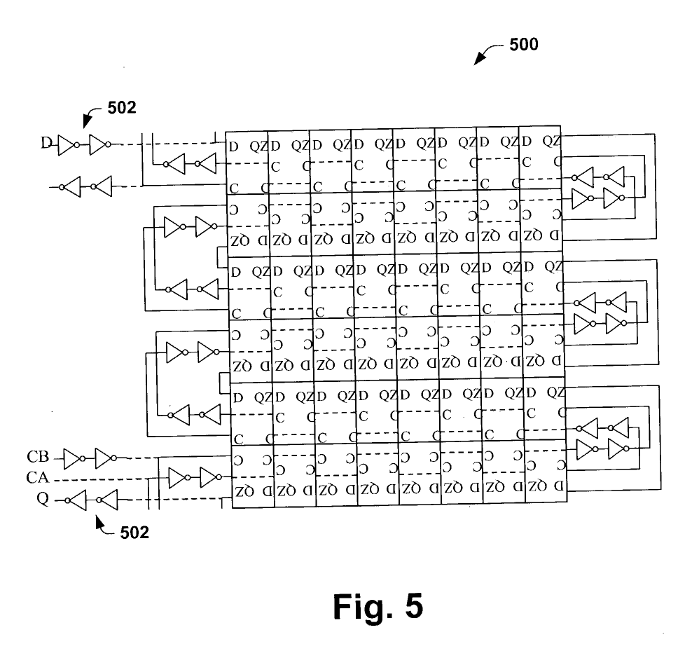

FIG. 5 illustrates another compact string of elements 500, similar to that depicted in FIG. 4, for testing an element of a particular type according to one or more aspects of the present invention. The elements are arranged in an array and in the example illustrated include latches of a particular type. The array is equivalent to a 6×4 flip-flop array and utilizes a two phase clock (e.g., CA and CB). The configuration includes multiple double inverter pairs 502 placed every so often within the string of elements to boost signal strength. A long length of chain (e.g., on the order of a thousand or more elements) would generally be utilized as the amount of time that it would take to develop characterization data from a much shorter chain would be impractical. The string thus facilitates obtaining real soft error data from real elements as they would work on actual devices in the field. Soft error or failure rates can thus be more accurately characterized as the need for simulations and/or guess work may be eliminated.

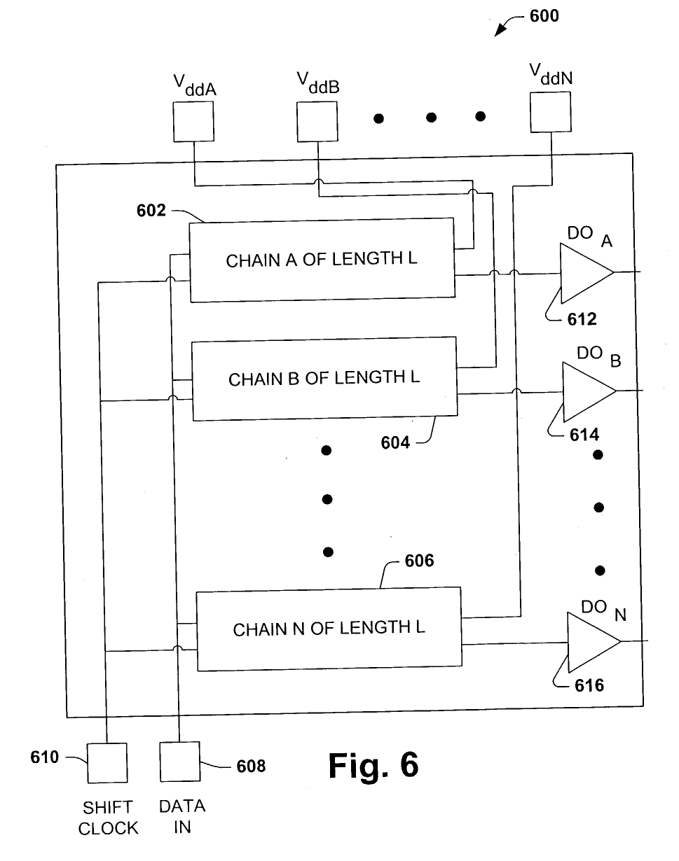

Turning to FIG. 6, an arrangement 600 of one or more components in a system adapted to determine and/or characterize soft error or failure rates in elements suitable for use as non-memory peripheral logic is depicted in block diagram form. The configuration illustrated provides for simultaneous testing of multiple, different elements. More particularly, a plurality of shift registers 602, 604, 606 are arranged in parallel, where the shift registers include respective synchronously clocked serial first in, first out (FIFO) buffers or chains of types of elements to be tested, namely chain A, chain B through chain N, N being an integer. The chains may be of equal length, namely length L in the example illustrated, to facilitate obtaining coincident test data for the different element types (e.g., respective failure rates given exposure to a particular type of radiation for a particular period of time, etc.). It will be appreciated, however, that the chains need not be of the same length. Nevertheless, it may easier to readout data from chains having equal length as the data output will be synchronized.

Data is supplied to the respective buffers by an input data source 608, and a shift clock 610 is also coupled to the respective element chains to synchronously clock the data into the buffers 602, 604, 606. Respective V_{dd} control sources are also included for the buffers, namely V_{ddA}, V_{ddB} through V_{ddN}, where N is an integer. This facilitates independently changing the voltages on the different shift registers, which may be important in achieving desired test data as soft error rates are in some instances affected by applied voltages. The data output from the chains, namely DO_{A}, DO_{B} through DO_{N}, N being an integer, goes to respective buffers 612, 614, 616 for holding and/or additional processing, such as for a comparison to input data to determine if any soft errors have occurred (e.g., whether any of a stream of 1's clocked into the chains have emerged as 0's).

With continued reference to FIG. 6, it will be appreciated that for purposes of the present invention, there can be any number of chains and that the chains can be of any length. Nevertheless, the length of the chains is likely on the order of a thousand or more elements to bring the test time down to a reasonable level (e.g., on the order of seconds or minutes). Such a large number of elements may be necessary because regardless of how sensitive a single cell or logic element may be, it may take a significant amount of time (e.g., on the order of days or even years) to obtain some failure rate test data for that element. Thus, many elements (of a particular element type) are chained together and data, in one example, is passed down the chain in a bucket brigade fashion to multiply the failure rate of the elements to reduce the test time.

It will be appreciated, however, that the length of the chains can be altered as is needed to obtain sufficient characterization data within a reasonable or acceptable time frame (e.g., depending upon the sensitivity of the elements being tested). Should chain lengths be able to be decreased, for example, more elements may be able to be tested simultaneously as more room may be available on a test chip. Thus, the number of element chains and corresponding inputs, outputs and control voltages can be adjusted as is appropriate.

In operation, a stream of data (e.g., all 1's, all 0's, alternating 1's and 0's) is fed into an element string. By way of example, should all 1's be fed into the string, a first 1 is fed in and clocked so that it goes into a first element. A second 1 is then fed in and clocked so that the first 1 is advanced to a second element and the second 1 fills the first element. The process continues until the respective elements in the string contain 1's.

In an exemplary static mode, an entire register may be filled with 1's and then a radiation source (not shown) is applied for some amount of time. The radiation source is then taken away or deactivated and the data is read out to obtain the soft error rate data. For example, all non 1's read out are indicative of soft errors produced by the radiation.

In an exemplary dynamic mode, data of a known pattern (e.g., all 1's, all 0's, alternating 1's and 0's) may be quickly and continuously written to the element strings while the elements are exposed to the radiation, and data output from the strings is constantly read (also while the elements are exposed to the radiation). Variations in the output data from the known clocked in pattern are indicative of soft errors.

Failure rates in a particular time frame can then be obtained for the respective types of elements being tested since the radiation exposure time, type and intensity are known, and the number of elements that fail during this exposure time period has been determined. This can be utilized to compute or estimate what an actual failure rate would be for the respective elements when the elements are implemented in the field.

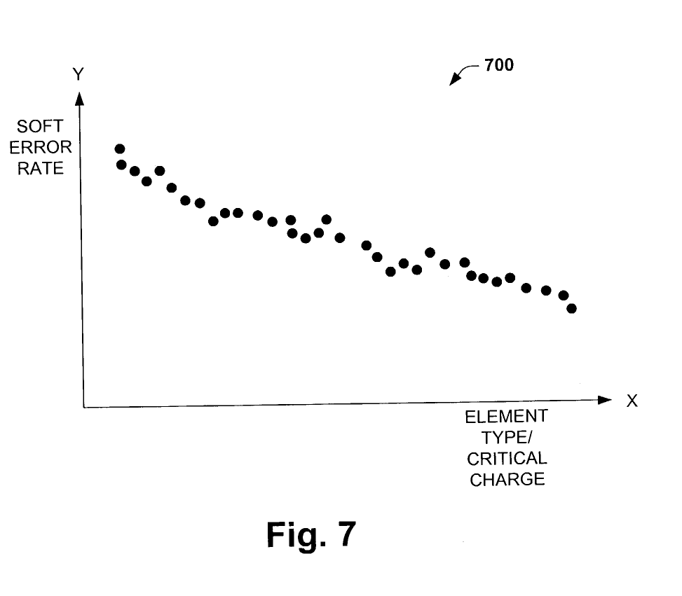

Turning now to FIG. 7, an exemplary plot 700 of element type/critical charge (x axis) versus respective failure rates for the elements (y axis) is depicted. In the example shown, the plot reveals a substantially linear curve illustrating that the failure rate decreases as the critical charge increases. It will be appreciated, however, that such a curve could have almost any form (e.g., exponential, logarithmic), and that similar graphs can be rendered for different test/operating conditions (e.g., radiation type, intensity and duration).

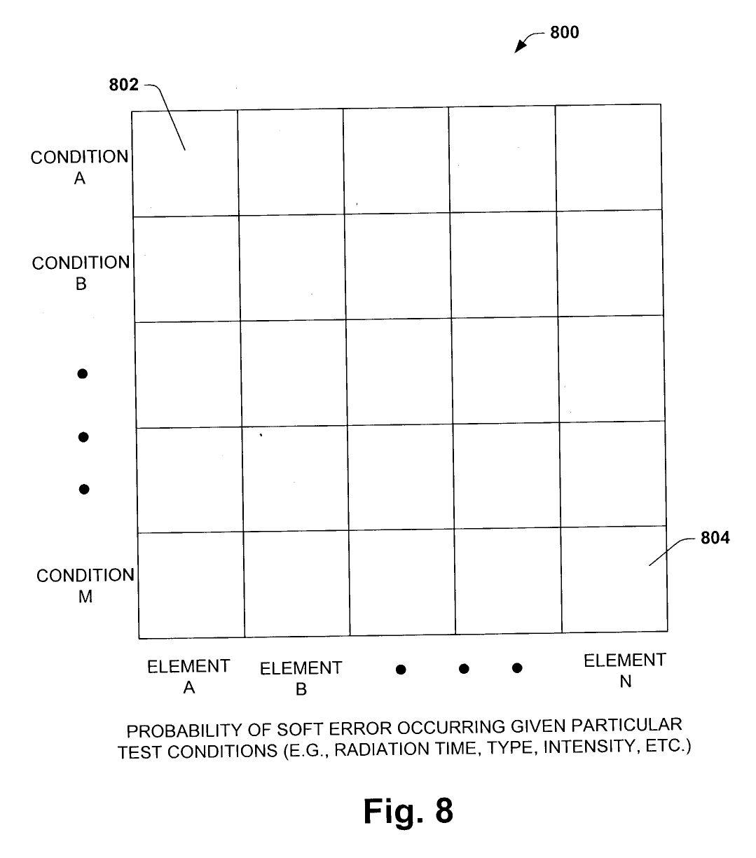

FIG. 8 illustrates an exemplary characterization box 800 which may, for example, be derived from one or more graphs, such as that depicted in FIG. 7 and/or from measured or computed data. The characterization box or table 800 includes entries for a plurality of different element types, namely elements A thru N, where N is an integer, and correlates respective probabilities of soft errors for those elements to a plurality of given test conditions, namely conditions A thru M, where M is also an integer. The test conditions emulate conditions that the elements may actually be exposed to when implemented in the field, and thus provide a metric which designers can consult when designing new products and/or diagnosing existing products.

It will be appreciated that it may be impractical to physically measure and obtain failure rate characterization data for all of the different types of elements that presently exist and/or that will be developed. Accordingly, error rates for some of the element types can be calculated from empirically determined data. Interpolation techniques can, for example, be utilized to develop error rate characterization data for some types of elements. For instance, empirical data from neighboring element types that may have relatively similar critical charges can be utilized to determine error rates for particular element types having critical charges that fall somewhere in between the critical charges of those neighboring element types. It may be prudent, for example, to calculate rather than measure soft error rates for those element types which are utilized infrequently in product design and whose failure rates are thus unlikely to have a widespread impact on products in the marketplace.

Additionally, the weakest and strongest versions of an element (e.g., those that are the most and least likely to exhibit soft errors due to fabrication at the process corners) may be utilized to define upper and lower limits of a characterization or performance box, such as that depicted in FIG. 8. For example, entry 802 may comprise a value indicative of a greatest propensity for exhibiting soft errors, while entry 804 may include a figure indicative of a lowest probability of soft errors occurring. This may be the case, for example, where element A has a lowest critical charge (making it highly susceptible to soft errors), while the other elements have increasingly greater critical charges, up to element N which has a greatest critical charge (making it least likely to exhibit soft errors). Also, condition A may have a greatest impact on the elements with regard to causing soft errors. For example, condition A may include application of a radiation of a type, intensity and/or duration that exacerbates soft errors. The severity of the conditions may decrease on down to condition M, such that the conditions have a lower and lower impact on the elements with regard to causing soft errors. The most influential condition (e.g., condition A) applied to the most susceptible element (e.g., element A) thus causes the entry 802 to reflect a greatest propensity for soft errors, while the least influential condition (e.g., condition M) applied to the least susceptible element (e.g., element N) results in entry 804 reflecting a lowest probability for the occurrence of soft errors. By defining the box based upon the failure rates of these best and worst performing elements, a performance window is created wherein subsequently encountered/tested element type should exhibit respective soft error rates that fall somewhere in between these extremes.

One or more aspects of the present invention thus provide for a mechanism that allows a choice to be made at a design stage regarding which particular element(s) to include in a product design to yield a final product that has a particular failure or soft error rate. Aspects of the present invention provide a metric to designers regarding which element(s) to utilize in producing a final product to achieve desired results (e.g., levels of product reliability). By way of example, designers who have access to ASIC cell libraries, including, for example, fliP-flop_{A}, flip-flop_{B}, flip-flop_{C}, etc. can selectively utilize theses elements as is needed to create desired devices. Obtained failure rate data, can also, for example, be utilized in association with simulation and modeling techniques so that an estimate of reliability can be provided for different element types and/or final products. This may be advantageous as it may be impractical to test every different type of logic element and develop failure rate characterization data therefore.

As such, a certain level of product reliability can be built in at the design stage. One or more aspects of the present invention can also facilitate diagnosis of existing product performance. For example, by knowing what elements are included in an existing product, the failure rates of those elements can be obtained from a database of failure rate characterization data to determine or predict what the failure or soft error rate of the existing product should be, and thus whether the actual failure rate of the existing product provides an indication that the product is or is not functioning as intended.

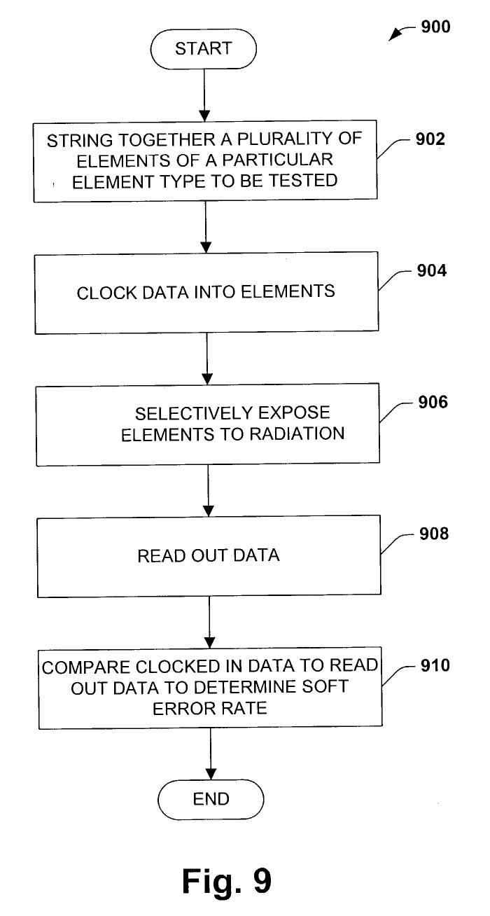

With reference now to FIG. 9, in accordance with one or more aspects of the present invention, a methodology 900 is illustrated for determining a soft error rate of a type of electronic circuit element suitable for use as non-memory peripheral logic in semiconductor memory devices. Although the methodology 900 is illustrated and described hereinafter as a series of acts or events, it will be appreciated that the present invention is not limited by the illustrated ordering of such acts or events. For example, some acts may occur in different orders and/or concurrently with other acts or events apart from those illustrated and/or described herein, in accordance with one or more aspects of the present invention. In addition, not all illustrated steps may be required to implement a methodology in accordance with the present invention. Furthermore, any methodologies according to the present invention may be implemented, to varying degrees, in association with the formation and/or processing of structures that may or may not be illustrated and described herein.

The methodology begins at 902 wherein a plurality of elements of a particular element type to be tested are strung together (e.g., as synchronously clocked serial first in, first out (FIFO) buffers or chains, where the output of one element feeds into or acts as an input to a subsequent element in the chain). At 904 data is clocked into the string of elements. A data source (e.g., of all 1's, all 0's, alternating 1's and 0's or any other known pattern of 1's and 0's) can, for example, be coupled to the string of elements and cycled into the elements by a clock signal which is also coupled to the string of elements. By way of example, should all 1's be fed into the string, a first 1 is fed in and clocked so that it goes into a first element in the string. A second 1 is then fed in and clocked so that the first 1 is advanced to a second element and the second 1 fills the first element. The process continues until the respective elements in the string contain 1's.

At 906, the elements in the string are selectively exposed to a source of radiation. The radiation is applied to mimic actual operating conditions the element will experience when actually implemented in final products. The radiation can thus be of a particular type, applied at particular intensity, applied for a particular period of time, etc. At 908 data is read out of the elements as the data passes through the length of elements and exits out through the last element in the chain. At 910 data input into the chain is compared to data read out of the chain to determine a soft error rate. Variations between the known clocked in pattern and the output data are indicative of failures or soft errors. The methodology then ends after 910.

It will be appreciated that the ordering of the acts is not absolute and/or to be construed in a limiting sense. For example, the methodology can be carried out in static as well as dynamic modes. In a static mode, the respective elements are filled with data (e.g., all 1's) prior to being exposed to radiation. The radiation is then applied for a particular period of time and then taken away from the string of elements before the data is read out from the elements. The known clocked in data stream is then compared to the output data to see if any soft errors have occurred. In a dynamic mode, data of a known pattern (e.g., all 1's, all 0's, alternating 1's and 0's) is quickly and continuously written to the element strings while the elements are exposed to the radiation, and data output from the strings is constantly read out and compared to input data while the elements remain exposed to the radiation.

Additionally, one or more acts of the methodology can be carried out concurrently to develop failure rate data for more than one type of element operating under the same (or different) test conditions. In such a scenario, an input source and a clock would likely be connected to respective chains of different type of elements to be tested. In this manner, data of a known pattern can be clocked into each of the respective chains and data output from the chains can be compared to this input data to see if any failures or soft errors have occurred in any of the respective chains of elements. The lengths of the chains in one example are the same for each of the types of elements to develop coincident test data. The lengths of the chains should also be long enough to develop a sufficient amount of test data in a reasonable amount of time. For example, chain lengths on the order of a thousand or more elements per chain should allow test data to be developed within several hours. As scaling continues and sensitivity increases accordingly, the lengths of chains can be reduced, which may allow more types of elements to be tested simultaneously as more chains can be squeezed onto a single test chip.

Failure rates in a particular time frame can then be obtained for the respective types of elements being tested since the radiation exposure time, type and intensity are known, and the number of elements that fail during this exposure time period can be been determined. This can be utilized to compute what an actual failure rate would be for the respective elements when the elements are implemented in the field.

Accordingly, it will be appreciated that one or more aspects of the present invention pertain to characterizing soft error or failure rates of electronic circuit elements, where the elements are suitable for use as non-memory peripheral logic in semiconductor memory devices, and where the probability of such soft error or failure rates increases as scaling continues and voltages and capacitances are thereby reduced, and as the elements, and more particularly charge sensitive interconnections or nodes thereof, are exposed to and affected by radiation.

Although the invention has been shown and described with respect to one or more implementations, equivalent alterations and/or modifications may be evident based upon a reading and understanding of this specification and the annexed drawings. The invention includes all such modifications and alterations and is limited only by the scope of the following claims. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary implementations of the invention. In addition, while a particular feature of the invention may have been disclosed with respect to only one of several implementations, such feature may be combined with one or more other features of the other implementations as may be desired and advantageous for any given or particular application. Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A method of testing for a soft error rate of a type of electronic circuit element suitable for use as non-memory peripheral logic in semiconductor memory devices comprising:
exposing a plurality of elements of the element type to be tested to radiation, wherein the elements are arranged in series as a string or as an XY array;
clocking data into the string of elements;
reading out the data after the elements have been exposed to the radiation;
comparing the read out data to the clocked in data; and
determining a soft error rate for the element type based upon the comparison.

2. The method of claim 1, wherein the data is continually clocked into and read out of the elements while the elements remain exposed to the radiation.

3. The method of claim 1, wherein data is clocked into the elements before exposing the elements to the radiation and the elements are exposed to the radiation for a particular period of time.

4. The method of claim 3, wherein the radiation is removed from the elements before the data is read out of the elements.

5. The method of claim 1, wherein the type of element comprises at least one of flip-flops, latches and combinatorial elements.

6. The method of claim 1, wherein the clocked in data is of a known pattern.

7. The method of claim 6, wherein the known pattern includes at least one of all 1's, all 0's and an alternating pattern of 1's and 0's.

8. The method of claim 1, wherein the string has a length of about a thousand or more elements.

9. The method of claim 1, wherein more than one type of element is to be tested and a plurality of elements corresponding to the respective element types are arranged as respective strings, the method further comprising:
concurrently clocking data of a known pattern into the respective strings of elements;
reading out the data from the respective strings after the elements have been exposed to the radiation;
comparing the read out data to the clocked in data for the respective element types; and
determining a soft error rate for the respective element types based upon the comparisons.

10. The method of claim 9, wherein the respective strings have an equal length.

11. A method of developing a catalog of performance criteria for an inventory of elements suitable for use as non-memory peripheral logic in semiconductor memory devices comprising:
determining, based upon empirical data, a soft error rate for a first element having a low critical charge;
determining, based upon empirical data, a soft error rate for a second element having a high critical charge; and
estimating respective soft error rates for one or more elements having respective soft error rates between that of the first and second elements.

12. The method of claim 11, wherein interpolation is utilized to calculate the respective soft error rates for the one or more elements.

13. The method of claim 11, wherein a soft error rate performance window is defined between the respective error rates of the first and second elements.

14. A method of reducing testing time required to obtain failure rate test data for elements suitable for use as non-memory peripheral logic in semiconductor memory devices:
stringing together a plurality of elements of the element type to be tested to amplify the effects of the test;
clocking data into the elements;
exposing the elements to radiation indicative of that to which the elements would be exposed in practice;
reading out the data after the elements have been exposed to the radiation;
comparing the read out data to the clocked in data; and
determining a soft error rate for the element type based upon the comparison.

15. A test system adapted to determine a soft error rate of a type of electronic circuit element suitable for use as non-memory peripheral logic in semiconductor memory devices comprising:
a string of elements of the type of element to be tested;
a component adapted to input data into the string;
a radiation source operable to expose the elements to radiation that mimics conditions the elements would encounter in operation;
a component operable to read out data from the string of elements; and
a component operable to compare the input data to the output data and determine whether the input data has changed upon passage through the string of elements and thus whether any soft errors have occurred.

16. The system of claim 15, wherein the component for inputting data comprises a clock and a data source.

17. The system of claim 15, wherein the input data comprises data of a known pattern.

18. The system of claim 17, wherein the known pattern includes at least one of all 1's, all 0's and an alternating pattern of 1's and 0's.

19. The system of claim 15, wherein the radiation source is operable to expose the string of elements to radiation of at least one of a particular type, intensity and exposure duration.

20. The system of claim 15, wherein the radiation source is operable to continually expose the string of elements to radiation while data is entered into and exits out of the string of elements

21. The system of claim 16 adapted to determine respective soft error rates of more than one type of element, the system further comprising:
respective strings of elements for the types of elements to be tested, the clock and data in source operatively coupled to the respective strings to simultaneously enter data into the respective strings, and the radiation source operative to expose all of the strings to radiation.

22. The system of claim 21, wherein the respective stings have an equal length.

23. The system of claim 22, wherein the respective strings have a length of about a thousand or more elements.
